(19) United States
(12) Patent Application Publication
(10) Pub. No.: US 2025/0280688 A1
(43) Pub. Date: Sep. 4, 2025

(54) DISPLAY PANEL AND MOBILE TERMINAL

(71) Applicant: Wuhan China Star Optoelectronics Semiconductor Display Technology Co., Ltd., Wuhan (CN)

(72) Inventor: Shenfu ZHANG, Wuhan (CN)

(21) Appl. No.: 17/613,500

(22) PCT Filed: Sep. 17, 2021
(86) PCT No.: PCT/CN2021/119084

§ 371 Date: May 27, 2025

(30) Foreign Application Priority Data
Sep. 9, 2021 (CN) 202111055130.1

(51) Int. Cl. H10K 59/35

(52) U.S. Cl. CPC H10K 59/353

(57) ABSTRACT

The present disclosure provides a display panel and a mobile terminal. The display panel further includes a plurality of light-emitting repeating units, the light-emitting repeating unit includes two adjacent light-emitting unit groups, the light-emitting unit group includes a plurality of sub-pixels, third electrodes of a plurality of third sub-pixels in the light-emitting unit group are electrically connected by a first wire, two adjacent light-emitting unit groups include at least two adjacent third sub-pixels, and two third electrodes corresponding to the two adjacent third sub-pixels are overlapped with a third light-emitting layer.

### TECHNICAL FIELD

The present disclosure relates to a field of display, and more particularly to a display panel and a mobile terminal.

### BACKGROUND

Compared with a liquid crystal display screen (LED), a display screen of an organic light-emitting semiconductor (OLED) is lighter and thinner, higher brightness, lower power consumption, faster response, higher definition, better flexibility, higher luminous efficiency, and capable of meeting new requirements of consumers for display technologies. More and more display manufacturers around the world have invested in research and development and production, and an industrialization process of the OLED is greatly promoted.

At present, various colors are displayed by using sub-pixels of red, green, and blue (RGB) three primary colors in a certain arrangement. In an initial stage of OLED displays, due to low pixel density (PPI, pixels per inch), the RGB three primary colors are usually distributed in a slit type and a foreground dot painting type. Subsequently, with an improvement of PPI, an aperture ratio of a metal photomask is required to be larger and larger, the arrangement of the RGB three primary colors gradually adopted a pixel arrangement manner, arranging red sub-pixels and green sub-pixels, and green sub-pixels and blue sub-pixels together respectively to form display pixel units, and full-color display is achieved through different arrangement manners of different pixel units in a whole panel. However, the full-color display of a display panel has pixel borrowing, so that a display effect is far inferior to the display panel with a standard RGB pixel arrangement.

### SUMMARY OF INVENTION

### Technical Issue

Embodiments of the present disclosure provide a display panel and a mobile terminal, so as to solve technical problems of further improving a full-color display effect of the display panel, at a same time, also improving a rate of space arrangement utilization of the display panel, reducing difficulty of design and production of a photomask, and improving a yield rate of product production.

### Solution to Issue

### Technical Solution

In order to solve the above problems, technical solutions provided in the present disclosure are as follows:

Embodiments of the present disclosure provides a display panel, including a plurality of sub-pixels, the plurality of sub-pixels includes:

A plurality of first sub-pixels configured to displaying a first color, the first sub-pixel includes a first electrode and a first light-emitting layer disposed on the first electrode.

A plurality of second sub-pixels configured to displaying a second color, the second sub-pixel includes a second electrode and a second light-emitting layer disposed on the second electrode.

A plurality of third sub-pixels configured to displaying a third color, the third sub-pixel includes a third electrode and a third light-emitting layer disposed on the third electrode, and the third light-emitting layer is overlapped with at least two adjacently disposed third electrodes.

The display panel further includes a plurality of light-emitting repeating units, each of the light-emitting repeating units includes two adjacently disposed light-emitting unit groups, and each of the light-emitting unit groups includes:

One of the first sub-pixels disposed in a center of a virtual rectangle.

At least one of the second sub-pixels disposed in the virtual rectangle and close to a side edge of the virtual rectangle.

At least two of the third sub-pixels disposed in the virtual rectangle and adjacent to a common side edge of the virtual rectangle, and the common side edge is a side edge of the virtual rectangle adjacent to the virtual rectangle of another adjacent light-emitting unit group.

Wherein third electrodes of the at least two of the third sub-pixels in the light-emitting unit group are electrically connected via a first wire.

In each of the light-emitting repeating units, the two adjacent light-emitting unit groups include at least two adjacent third sub-pixels.

In the display panel of the present disclosure, each of the light-emitting unit groups includes at least two of the second sub-pixels, and second electrodes of the at least two of the second sub-pixels of each of the light-emitting unit groups are electrically connected via a second wire.

In the display panel of the present disclosure, the second light-emitting layer is overlapping disposed with at least two adjacently disposed second electrodes, a plurality of second sub-pixels of two adjacent light-emitting repeating units include at least one second sub-pixel group, and each second sub-pixel group includes at least two of the second sub-pixels, and the at least two of the second sub-pixels are respectively disposed in two light-emitting repeating units and disposed adjacent to each other.

In the display panel of the present disclosure, two of the second sub-pixels are disposed in one virtual rectangle, and the two of the second sub-pixels are respectively disposed at two top corners of the virtual rectangle distal to the common side edge, in any four of the adjacent light-emitting repeating units, four of the adjacent second sub-pixels share one second light-emitting layer, and the second light-emitting layer is overlappingly disposed with four of the second electrodes.

In the display panel of the present disclosure, two of the third sub-pixels are disposed in one virtual rectangle, and two of the third sub-pixels are respectively disposed at two top corners of the virtual sub-rectangle close to the common side edge, and in a direction parallel to the common side edge, four of the adjacent third sub-pixels are disposed in any two adjacent light-emitting repeating units, the four of the third sub-pixels share one third light-emitting layer, and the third light-emitting layer is overlapping with four of the third electrodes.

In the display panel of the present disclosure, in one virtual rectangle, a number of the second sub-pixels is same as a number of the third sub-pixels.

In the display panel of the present disclosure, the second light-emitting layer is overlapping disposed with at least two adjacently disposed second electrodes, at least one of the second sub-pixels in the light-emitting unit group is disposed close to the common side edge, two adjacent light-emitting unit groups include two of the second sub-pixels at least partially adjacent to each other, two adjacent second sub-pixels include a second common edge, and the second common edge coincides with the common side edge of the virtual rectangle.

In the display panel of the present disclosure, the two adjacent light-emitting unit groups are symmetrically disposed with respect to the common side edge.

In the display panel of the present disclosure, an area of the first sub-pixel is greater than an area of the second sub-pixel, and an area of the first sub-pixel is greater than an area of the third sub-pixel.

In the display panel of the present disclosure, the first sub-pixels, the second sub-pixels, and the third sub-pixels are any combination of red sub-pixels, green sub-pixels, and blue sub-pixels.

The present disclosure further provides a mobile terminal, including a display panel and a terminal body, the terminal body and the display panel are combined into a whole, and the display panel includes: a plurality of sub-pixels, the plurality of sub-pixels including:

A plurality of first sub-pixels configured to displaying a first color, the first sub-pixel includes a first electrode and a first light-emitting layer disposed on the first electrode.

A plurality of second sub-pixels configured to displaying a second color, the second sub-pixel includes a second electrode and a second light-emitting layer disposed on the second electrode.

A plurality of third sub-pixels configured to displaying a third color, the third sub-pixel includes a third electrode and a third light-emitting layer disposed on the third electrode, and the third light-emitting layer is overlapped with at least two adjacently disposed third electrodes.

The display panel further includes a plurality of light-emitting repeating units, each of the light-emitting repeating units includes two adjacently disposed light-emitting unit groups, and each of the light-emitting unit groups includes:

One of the first sub-pixels disposed in a center of a virtual rectangle.

At least one of the second sub-pixels disposed in the virtual rectangle and close to a side edge of the virtual rectangle.

At least two of the third sub-pixels disposed in the virtual rectangle and adjacent to a common side edge of the virtual rectangle, and the common side edge is a side edge of the virtual rectangle adjacent to the virtual rectangle of another adjacent light-emitting unit group.

Wherein third electrodes of the at least two of the third sub-pixels in the light-emitting unit group are electrically connected via a first wire.

In each of the light-emitting repeating units, the two adjacent light-emitting unit groups include at least two adjacent third sub-pixels.

In the mobile terminal of the present disclosure, each of the light-emitting unit groups includes at least two of the second sub-pixels, and second electrodes of the at least two of the second sub-pixels of each of the light-emitting unit groups are electrically connected via a second wire.

In the mobile terminal of the present disclosure, the second light-emitting layer is overlapping disposed with at least two adjacently disposed second electrodes, a plurality of second sub-pixels of two adjacent light-emitting repeating units include at least one second sub-pixel group, and each second sub-pixel group includes at least two of the second sub-pixels, and the at least two of the second sub-pixels are respectively disposed in two light-emitting repeating units and disposed adjacent to each other.

In the mobile terminal of the present disclosure, two of the second sub-pixels are disposed in one virtual rectangle, and the two of the second sub-pixels are respectively disposed at two top corners of the virtual rectangle distal to the common side edge, in any four of the adjacent light-emitting repeating units, four of the adjacent second sub-pixels share one second light-emitting layer, and the second light-emitting layer is overlapping disposed with four of the second electrodes.

In the mobile terminal of the present disclosure, two of the third sub-pixels are disposed in one virtual rectangle, and two of the third sub-pixels are respectively disposed at two top corners of the virtual sub-rectangle close to the common side edge, and in a direction parallel to the common side edge, four of the adjacent third sub-pixels are disposed in any two adjacent light-emitting repeating units, the four of the third sub-pixels share one third light-emitting layer, and the third light-emitting layer is overlapping disposed with four of the third electrodes.

In the mobile terminal of the present disclosure, a number of the second sub-pixels is same as a number of the third sub-pixels.

In the mobile terminal of the present disclosure, the second light-emitting layer is overlapping disposed with at least two adjacently disposed second electrodes, at least one of the second sub-pixels in the light-emitting unit group is disposed close to the common side edge, two adjacent light-emitting unit groups include two of the second sub-pixels at least partially adjacent to each other, two adjacent second sub-pixels include a second common edge, and the second common edge coincides with the common side edge of the virtual rectangle.

In the mobile terminal of the present disclosure, the two adjacent light-emitting unit groups are symmetrically disposed with respect to the common side edge.

In the mobile terminal of the present disclosure, an area of the first sub-pixel is greater than an area of the second sub-pixel, and an area of the first sub-pixel is greater than an area of the third sub-pixel.

In the mobile terminal of the present disclosure, the second sub-pixels, and the third sub-pixels are any combination of red sub-pixels, green sub-pixels, and blue sub-pixels.

### Beneficial Effect of Invention

### Beneficial Effect

In the present disclosure, the display panel includes the plurality of light-emitting repeat units, each of the light-emitting repeating units includes two adjacently disposed light-emitting unit groups, and each of the light-emitting unit groups includes one of the first sub-pixels, at least one of the second sub-pixels, and at least two of the third sub-pixels. Wherein third electrodes of the at least two of the third sub-pixels in the light-emitting unit group are electrically connected via the first wire, so that one light-emitting unit group can realize white light display without using sub-pixels of adjacent structures, thereby effectively improving a display effect of the display panel, so that display color of the display panel is richer. At the same time, at least two third electrodes are connected in series via the first wire in a single light-emitting unit group, so that third pixels in the light-emitting unit group can be driven synchronously, a risk of display anomalies is reduced, and device performance is improved. The two adjacent light-emitting unit groups include at least two adjacent third sub-pixels, and two third electrodes corresponding to the two adjacent third sub-pixels are overlapping disposed with one third light-emitting layer, so that while a structure of the present disclosure realizes full-color display, sub-pixels of a same color can share a photomask opening, which reduces difficulty of design and production of a photomask, and improves production efficiency.

### BRIEF DESCRIPTION OF DRAWINGS

### Description of Drawings

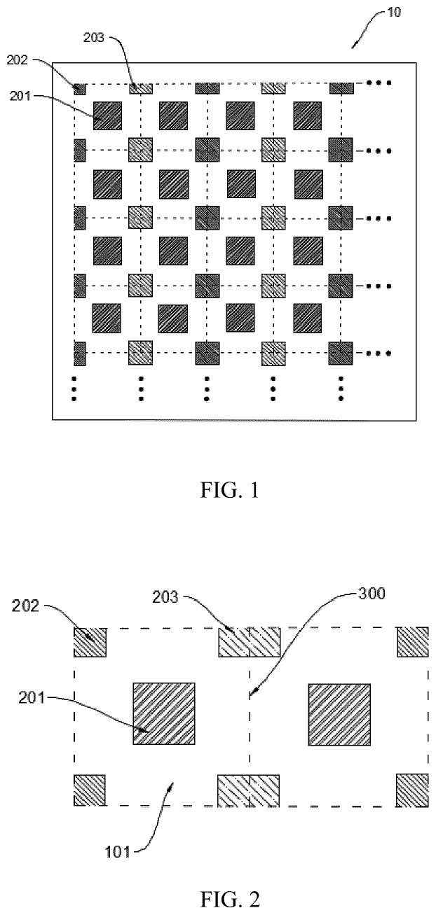

FIG. 1 is a schematic diagram of a pixel structure of a display panel provided by an embodiment of the present disclosure.

FIG. 2 is a schematic diagram of a pixel arrangement of a light-emitting repeating unit with third sub-pixels disposed at top corners of a virtual rectangle close to a common side edge provided by an embodiment of the present disclosure.

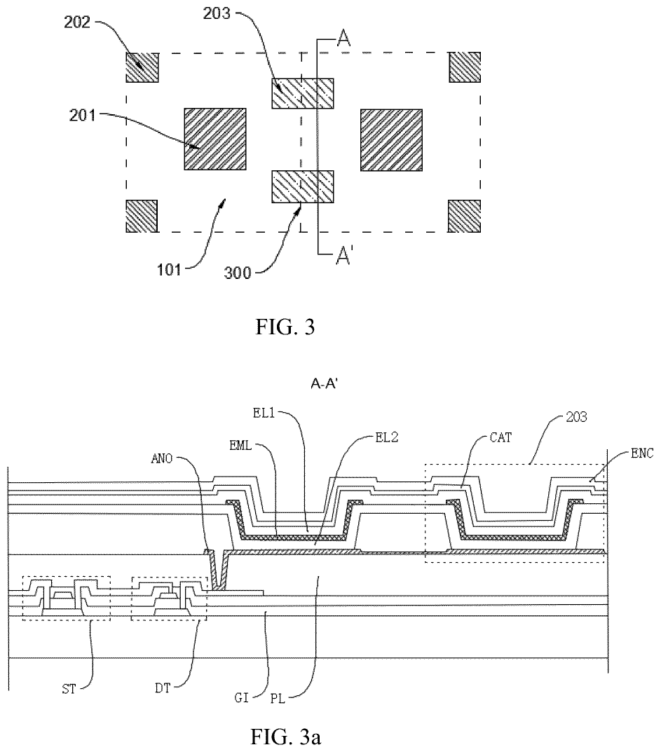

FIG. 3 is a schematic diagram of a pixel arrangement of a light-emitting repeating unit with second sub-pixels disposed at top corners of a virtual rectangle distal to a common side edge provided by an embodiment of the present disclosure.

FIG. 3a is a cross-sectional view taken along line A-A′ shown in FIG. 3 of the present disclosure.

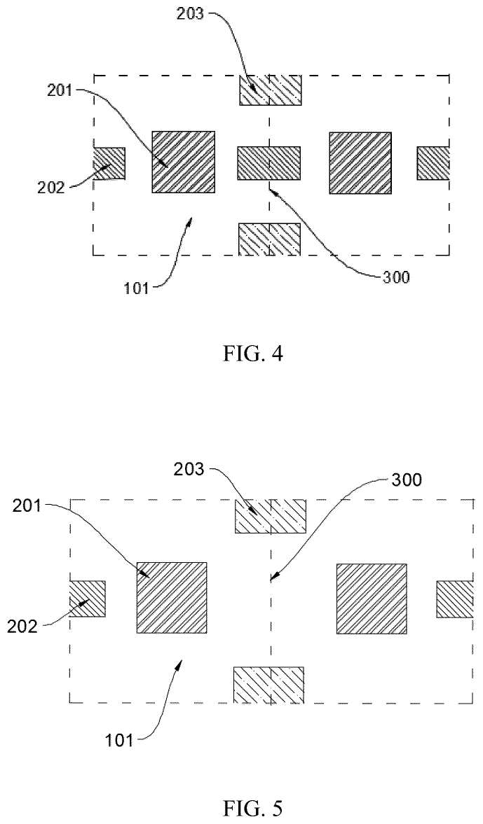

FIG. 4 is a schematic diagram of a pixel arrangement of a light-emitting repeating unit with second sub-pixels disposed on a common side edge provided by an embodiment of the present disclosure.

FIG. 5 is a schematic diagram of a pixel arrangement of a light-emitting repeating unit with only one second sub-pixel in a virtual rectangle provided by an embodiment of the present disclosure.

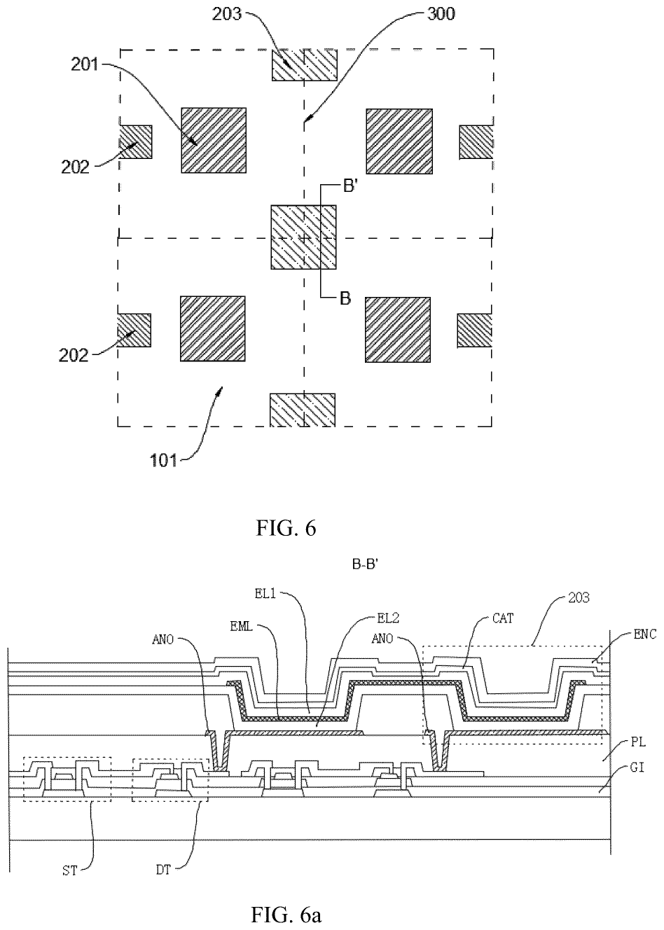

FIG. 6 is a schematic diagram of a pixel arrangement of two adjacent light-emitting repeating units provided by an embodiment of the present disclosure.

FIG. 6a is a cross-sectional view taken along line B-B′ shown in FIG. 6 of the present disclosure.

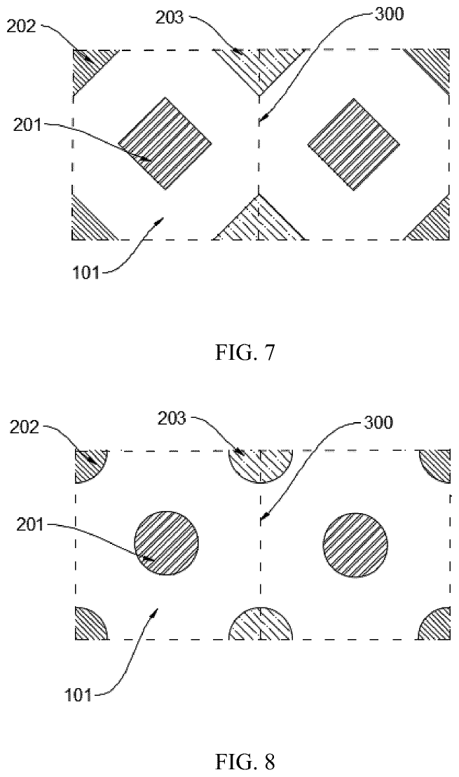

FIG. 7 is a schematic diagram of a pixel arrangement of a light-emitting repeating unit with triangular second sub-pixels and triangular third sub-pixels provided by an embodiment of the present disclosure.

FIG. 8 is a schematic diagram of a pixel arrangement of a light-emitting repeating unit with circular first sub-pixels provided by an embodiment of the present disclosure.

### EMBODIMENTS OF INVENTION

### Embodiments of the Present Invention

The present disclosure provides a dimming layer for a display module and a display module, in order to make objectives, technical solutions and effects of the present disclosure clearer, the present disclosure is further described in detail below with reference to accompanying drawings and embodiments. It's understandable that specific embodiments described are only used to explain the present disclosure, and are not intended to limit the present disclosure.

Embodiments of the present disclosure provide a display panel and a preparation method thereof. The following are detailed descriptions. It's understandable that an order of the following embodiments is not limited to a preferred order of the embodiments.

In a current product design, in order to pursue a higher PPI of a display panel 10, in a pixel unit, a sub-pixel is usually shared with an adjacent pixel unit, for example, a red sub-pixel and a green sub-pixel form a pixel unit, and the green sub-pixel and a blue sub-pixel form another pixel unit, full-color display is achieved through different arrangement manners of different pixel units in a whole panel, since a pixel structure realizes full-color display by sharing the sub-pixel of the adjacent pixel unit, although the structure has a higher PPI, a display effect is not as good as a full-color display effect achieved by a pixel structure without sharing a pixel. When displaying white light, the pixel unit with shared the pixel cannot independently display RGB three colors, when displaying white light, it is necessary to borrow the sub-pixel of the adjacent pixel unit, resulting in a decrease in display fineness.

The present embodiment solves the above problem, and the present disclosure provides following technical solutions, the present disclosure is further described below with reference to accompanying drawings and embodiments.

Refer to FIGS. 1-3, FIGS. 4-6, and FIGS. 7-8, the present disclosure provides a display panel 10, including a plurality of sub-pixels, the plurality of sub-pixels including:

A plurality of first sub-pixels 201 configured to displaying a first color, the first sub-pixel 201 includes a first electrode and a first light-emitting layer disposed on the first electrode.

A plurality of second sub-pixels 202 configured to displaying a second color, the second sub-pixel 202 includes a second electrode and a second light-emitting layer disposed on the second electrode.

A plurality of third sub-pixels 203 configured to displaying a third color, the third sub-pixel 203 includes a third electrode and a third light-emitting layer disposed on the third electrode, and the third light-emitting layer overlaps at least two adjacently disposed third electrodes.

The display panel 10 further includes a plurality of light-emitting repeating units, each of the light-emitting repeating units includes two adjacently disposed light-emitting unit groups 101, and each of the light-emitting unit groups 101 includes:

One of the first sub-pixels 201 disposed in a center of a virtual rectangle.

At least one of the second sub-pixels 202 disposed in the virtual rectangle and close to a side edge of the virtual rectangle.

At least two of the third sub-pixels 203 disposed in the virtual rectangle and adjacent to a common side edge 300 of the virtual rectangle, and the common side edge is a side edge of the virtual rectangle adjacent to a virtual rectangle of another adjacent light-emitting unit group 101.

Wherein third electrodes of the at least two of the third sub-pixels 203 in the light-emitting unit group 101 are electrically connected via a first wire.

In each of the light-emitting repeating units, the two adjacent light-emitting unit groups 101 include at least two adjacent third sub-pixels 203.

Specifically, the display panel 10 includes: the plurality of first sub-pixels 201 configured to displaying the first color, the plurality of second sub-pixels 202 configured to displaying the second color, and the plurality of third sub-pixels 203 configured to displaying the third color. The first sub-pixel 201, the second sub-pixel 202, and the third sub-pixel 203 each includes one, two, or more driving components, a pixel electrode connected to the driving components, a cathode disposed opposite to the pixel electrode, and an organic light-emitting layer disposed between the pixel electrode and the cathode. The first sub-pixels 201, the second sub-pixels 202, and the third sub-pixels 203 are disposed on a substrate according to a structure described below to form an organic light-emitting display panel 10.

Specifically, the display panel 10 further includes the plurality of light-emitting repeating units disposed adjacently, the plurality of light-emitting repeating units may be a lattice structure arranged in rows and columns, and edges of adjacent light-emitting repeating units are adjacent to each other.

Specifically, each of the light-emitting repeating units includes two adjacently disposed light-emitting unit groups 101, and each of the light-emitting unit groups 101 includes:

One of the first sub-pixels 201, which may be a blue sub-pixel, is disposed at the center of the virtual rectangle, and a shape of the first sub-pixel 201 is not limited. It is understandable that the first sub-pixel 201 is disposed at a center position, so that an arrangement structure of the pixel structure can be more reasonable, a light emission is more uniform, and at the same time, a process of subsequent metal wiring is also more convenient.

At least one of the second sub-pixels 202, which may be a green sub-pixel and a shape of the second sub-pixel 202 is not limited, is disposed in the virtual rectangle and close to a side edge of the virtual rectangle, the side edge is not limited, and may be the common side edge 300 of the virtual rectangle of two adjacent light-emitting unit groups 101, as shown in FIG. 4, or it may be disposed on a non-common side edge of the virtual rectangle of the light-emitting unit group 101, as shown in FIG. 5 and FIG. 6. Specifically, the second sub-pixel 202 may also be disposed at a corner of the virtual rectangle distal to the common side edge 300, as shown in FIGS. 1-3.

At least two of the third sub-pixels 203, it should be noted that there are gaps between the plurality of third sub-pixels 203 in a same light-emitting unit group 101, the third sub-pixels 203 may be red sub-pixels, disposed in the virtual rectangle and adjacent to the common side edge 300 of the virtual rectangle, and the common side edge 300 is a side edge of the virtual rectangle adjacent to the virtual rectangle of another adjacent light-emitting unit group 101.

Wherein as shown in FIG. 3a, third electrodes of the at least two of the third sub-pixels 203 in the light-emitting unit group 101 are electrically connected via the first wire, so that the third sub-pixels 203 of a same color in the same light-emitting unit group 101 can be synchronously driven.

In each of the light-emitting repeating units, the two adjacent light-emitting unit groups 101 include at least two adjacent third sub-pixels 203, two third electrodes corresponding to the two adjacent third sub-pixels 203 are overlappingly disposed with a third light-emitting layer. It's understandable that in the light-emitting repeating unit, since the third sub-pixels 203 in the light-emitting unit groups 101 are all adjacent to the common side edge 300 of the virtual rectangle, and there is a gap between the at least two of third sub-pixels 203 in one light-emitting unit group 101, therefore at least two of adjacent third electrodes are respectively disposed in the two light-emitting unit groups 101, by adopting the arrangement, in the light-emitting repeating unit, the two adjacent third sub-pixels 203 in the two adjacent light-emitting unit groups 101 can share one third light-emitting layer, so that while the display panel 10 realizes full-color display, difficulty of manufacturing a photomask of the display panel 10 can also be reduced, a yield rate of production is also improved, and a probability of color mixing in production country is also reduced.

Specifically, a manner in which the third electrodes of the at least two of the third sub-pixels 203 are electrically connected via the first wire is shown in FIG. 3a, FIG. 3a is a cross-sectional view taken along line A-A′ shown in FIG. 3. ANO is an anode of the third sub-pixel 203, which is used to cooperate with a cathode to drive a light-emitting layer to emit light after being connected to a driving unit, EL1 is an electron transport layer and an electron injection layer of the third sub-pixel 203, EL2 is a hole injection layer and a hole transport layer, CAT is the cathode of the third sub-pixel 203, EML is the light-emitting layer, ST is a switch control unit, DT is a driving unit, GI is a gate insulating layer, PL is a flat layer, and ENC is a encapsulation layer, it can be seen from FIG. 3a that anodes of two third sub-pixels 203 are connected in series, and are controlled by one driving unit and one switch control unit, thereby realizing synchronous switching.

By disposing the first sub-pixel 201, the second sub-pixel 202, and the third sub-pixel 203 in each of the light-emitting unit groups 101, so that one light-emitting unit group 101 can realize white light display without using sub-pixels of adjacent structures, thereby effectively improving the display effect of the display panel 10, so that display color of the display panel 10 is richer. At the same time, as shown in FIG. 3a, there are two third sub-pixels 203 in a single light-emitting unit group 101 as an example, and two third electrodes corresponding to the two third sub-pixels 203 in the light-emitting unit group are connected in series via the first wire, so that the two third sub-pixels 203 of a same color in the same light-emitting unit group 101 can be turned on or turned off simultaneously, thereby reducing a risk of display anomalies of the display panel 10, and effectively improving device performance.

It's understandable that, in the present disclosure, the display panel 10 includes the plurality of light-emitting repeating units 101, each of the light-emitting repeating units includes two adjacently disposed light-emitting unit groups 101, and each of the light-emitting unit groups 101 includes: one of the first sub-pixels 201, at least one of the second sub-pixels 202, and at least two of the third sub-pixels 203. Wherein, in the light-emitting unit group 101, at least two third electrodes of the third sub-pixel 203 are electrically connected via the first wire, so that one light-emitting unit group 101 can realize white light display without using sub-pixels of adjacent structures, thereby effectively improving the display effect of the display panel 10, so that the display color of the display panel 10 is richer. The at least two third electrodes of a same color are connected in series via the first wire in a single light-emitting unit group, so that third pixels in the light-emitting unit group 101 can be driven synchronously, the risk of display anomalies is reduced, and device performance is improved. The two adjacent light-emitting unit groups 101 include at least two adjacent third sub-pixels 203, and two third electrodes corresponding to the two adjacent third sub-pixels 203 overlaps one third light-emitting layer, so that while a structure of the present disclosure realizes full-color display, sub-pixels of a same color can share a photomask opening, which reduces difficulty of design and production of the photomask.

In an embodiment, as shown in FIG. 3 and FIG. 4, each of the light-emitting unit groups 101 includes at least two of the second sub-pixels 202, and second electrodes of the at least two of the second sub-pixels 202 of the light-emitting unit group 101 are electrically connected via a second wire.

Specifically, when one light-emitting unit group 101 includes at least two second sub-pixels 202, the second wire is arranged to connect the second electrodes corresponding to the at least two of the second sub-pixels 202 in the same light-emitting unit group 101 in series, so that the plurality of second sub-pixels 202 can be driven synchronously, and a specific connection structure is same as a connection structure of the plurality of third sub-pixels 203.

It's understandable that by disposing three color sub-pixels in the same light-emitting unit group 101, which includes one of the first sub-pixel 201, at least two of the second sub-pixels 202, and at least two of the third sub-pixels 203, so that one light-emitting unit group 101 can realize white light display without using sub-pixels of adjacent structures, thereby effectively improving the display effect of the display panel 10, so that display color of the display panel 10 is richer. By disposing at least two second sub-pixels 202 and disposing at least two third sub-pixels 203, light emission of the light-emitting unit group 101 can be more uniform. At the same time, in a single light-emitting unit group 101, at least two second pixel electrodes of a same color are connected in series via the first wire, so that a plurality of second pixels in the light-emitting unit group 101 can be driven synchronously, thereby reducing the risk of display anomalies of the display panel 10, and effectively improving device performance.

In an embodiment, as shown in FIG. 1, the second light-emitting layer is overlappingly disposed with at least two adjacently disposed second electrodes, a plurality of second sub-pixels 202 of two adjacent light-emitting repeating units include at least one second sub-pixel 202 group, and each second sub-pixel 202 group includes at least two of the second sub-pixels 202, and the at least two of the second sub-pixels are respectively disposed in two light-emitting repeating units and disposed adjacent to each other.

Specifically, the second sub-pixels 202 in the second pixel group are disposed on the non-common side edge of the virtual rectangle, so that two adjacent second sub-pixels 202 of two adjacent light-emitting repeating units are closely disposed to each other, so that the two adjacent second sub-pixels 202 can share an opening on one photomask.

It's understandable that by disposing the second sub-pixels 202 in the second pixel group at positions close to an edge of the virtual rectangle, so that the adjacent sub-pixels of a same color in two or more adjacent light-emitting repeating units can be spliced together to form a large sub-pixel of the same color. During a production process of the display panel 10, for sub-pixels of a same color, one photomask opening can be used, fineness of the photomask opening is reduced, difficulty of manufacturing the photomask is reduced, production efficiency is improved, a probability of color mixing is reduced, and a yield rate of product production is improved.

In an embodiment, as shown in FIGS. 1-3 and FIGS. 7-8, two of the second sub-pixels 202 are disposed in one virtual rectangle, and the two of the second sub-pixels 202 are respectively disposed at two top corners of the virtual rectangle distal to the common side edge 300, in any four of the adjacent light-emitting repeating units, four of the adjacent second sub-pixels 202 share one second light-emitting layer, and the second light-emitting layer is overlapping disposed with four of the second electrodes.

It's understandable that by disposing the second sub-pixels 202 at the two top corners of the virtual rectangle distal to the common side edge 300, after a plurality of repeating units are disposed on the substrate, four of the adjacent second sub-pixels 202 are gathered at top corners to form a spliced second sub-pixel 202 spliced by the four of the second sub-pixels 202. Since the four of the second sub-pixels 202 have a same color and are adjacent to each other, a pixel opening can be shared, an aperture ratio of the pixel is further increased, preparation difficulty of a pixel mask plate is reduced, and the yield rate of production is improved.

In an embodiment, as shown in FIG. 1 and FIGS. 5-6a, two of the third sub-pixels 203 are disposed in one virtual rectangle, and the two of the third sub-pixels 203 are respectively disposed at two top corners of the virtual sub-rectangle close to the common side edge 300, as shown in FIG. 6, and in a direction parallel to the common side edge 300, four of the adjacent third sub-pixels 203 are disposed in any two adjacent light-emitting repeating units, the four of the third sub-pixels 203 share one third light-emitting layer, and the third light-emitting layer is overlapping disposed with four of the third electrodes.

As shown in FIG. 6a, FIG. 6a is a cross-sectional view taken along line B-B′ shown in FIG. 6. ANO is an anode of the third sub-pixel 203, EL1 is an electron transport layer and an electron injection layer of the third sub-pixel 203, EL 2 is a hole injection layer and a hole transport layer, CAT is a cathode of the third sub-pixel 203, EML is a light-emitting layer, ST is a switch control unit, DT is a driving unit, GI is a gate insulating layer, PL is a flat layer, and ENC is a packaging layer. It can be seen from FIG. 6 that third sub-pixels close to each other may share a same light-emitting layer (FIG. 6a shows the same light-emitting layer is shared), but anodes of the two third sub-pixels 203 are independent of each other (i.e., driven by two driving units respectively), which can reduce difficulty of opening the photomask during a preparation process.

It's understandable that by disposing the third sub-pixels 203 at the two top corners of the virtual rectangle close to the common side edge 300, after a plurality of repeating units are disposed on the substrate, a plurality of third sub-pixels 203 at top corners of a plurality of repeating units are close to each other, the aperture ratio of the pixel is further increased, preparation difficulty of a pixel photomask is reduced, at the same time, a problem of color mixing can be effectively prevented, and the yield rate of production is improved.

In an embodiment, in one virtual rectangle, a number of the second sub-pixels 202 is same as a number of the third sub-pixels 203.

It's understandable that by disposing a same number of the second sub-pixels 202 as the number of the third sub-pixels 203, a uniformity of display of the pixel units is improved, at the same time, space utilization can be maximized, and a PPI of the display panel 10 can be improved.

In an embodiment, as shown in FIG. 4, the second light-emitting layer is overlapping disposed with at least two adjacently disposed second electrodes, at least one of the second sub-pixels 202 in the light-emitting unit group 101 is disposed close to the common side edge 300, two adjacent light-emitting unit groups 101 include two of the second sub-pixels 202 at least partially adjacent to each other, two adjacent second sub-pixels 202 include a second common edge, and the second common edge coincides with the common side edge 300 of the virtual rectangle.

It's understandable that by adopting the technical solution, fineness of the photomask opening can be further reduced, two adjacent second sub-pixels 202 can share one light-emitting layer, difficulty of preparation is reduced, and a cost of production is further reduced.

In an embodiment, the two adjacent light-emitting unit groups 101 are symmetrically arranged with respect to the common side edge 300.

It is understandable that by symmetrically disposing the two light-emitting unit groups 101, sub-pixels in two virtual rectangles are symmetrically disposed with respect to the common side edge 300, so that a pattern of repeating light-emitting unit can be more orderly, a change of bright and dark lines caused by inconsistent light-emitting distances is reduced, and the uniformity of display is improved.

In an embodiment, an area of the first sub-pixel 201 is greater than an area of the second sub-pixel 202, and the area of the first sub-pixel 201 is greater than an area of the third sub-pixel 203.

It is understandable that, by adopting the arrangement, file three-color pixels have uneven lifetimes due to their own materials, pixels with a short lifetime can be set as the first sub-pixels 201, and by increasing an opening area of the first sub-pixel 201, the lifetime of short-lived pixels can be prolonged, so that a service life of the display panel 10 can be further prolonged. For example, currently, a material problem is limited in the RGB three colors, and a lifetime of blue pixels is shortest, therefore by increasing the opening area of the blue pixel, so that a ratio of RGB opening area is balanced according to status and needs of the display device, so that the service life of the display device can be effectively prolonged.

In an embodiment, the first sub-pixels 201, the second sub-pixels 202, and the third sub-pixels 203 are any combination of red sub-pixels, green sub-pixels, and blue sub-pixels.

Specifically, the first sub-pixels 201 may be blue sub-pixels, the second sub-pixels 202 may be green sub-pixels, and the third sub-pixels 203 may be red sub-pixels.

Specifically, as shown in FIGS. 7-8, a shape of the first sub-pixel 201 may be one of a circle, a triangle, a rectangle, and a regular polygon.

A shape of the second sub-pixel 202 may be one of a sector, a triangle, a rectangle, and a polygon.

A shape of the third sub-pixel 202 may be one of a sector, a triangle, a rectangle, and a polygon.

Specifically, in the virtual rectangle, the area of each of the first sub-pixels 201 is same, and the shape of each of the first sub-pixels 201 is consistent, and/or

The area of each of the second sub-pixels 202 is same, and the shape of each of the second sub-pixels 202 is consistent; and/or

The area of each of the third sub-pixels 203 is same, and the shape of each of the third sub-pixels 203 is consistent.

The present disclosure further provides a mobile terminal, including the display panel 10 described in any of the above embodiments and a terminal body, and the terminal body and the display panel 10 are combined into a whole.

In summary, in the present disclosure, the plurality of light-emitting repeating units are disposed in the display panel 10, each of the light-emitting repeating units includes two adjacently disposed light-emitting unit groups 101, each of the light-emitting unit groups 101 includes one of the first sub-pixels 201, at least one of the second sub-pixels 202, and at least two of the third sub-pixels 203. In the light-emitting unit group 101, third electrodes of the at least two of the third sub-pixels 203 are electrically connected via the first wire, so that each of the light-emitting unit groups can realize white light display without using sub-pixels of adjacent structures, thereby effectively improving the display effect of the display panel, so that display color of the display panel 10 is richer. At the same time, at least two third electrodes are connected in series via the first wire in a single light-emitting unit group, so that third pixels in the light-emitting unit group can be driven synchronously, the risk of display anomalies is reduced, and device performance is improved. Two adjacent light-emitting unit groups 101 include at least two adjacent third sub-pixels 203, and two third electrodes corresponding to the two adjacent third sub-pixels are overlapping disposed with one third light-emitting layer, so that while a structure of the present disclosure realizes full-color display, sub-pixels of a same color can share a photomask opening, which reduces difficulty of design and difficulty of production of the photomask, and improves production efficiency.

It is understandable that for those of ordinary skill in the art, equivalent substitutions or changes may be made according to the technical solutions and inventive concept of the present disclosure, and all these changes or substitutions should fall within the protection scope of the appended claims of the present disclosure.

What is claimed is:

1. A display panel, comprising a plurality of sub-pixels, the plurality of sub-pixel comprises:
a plurality of first sub-pixels configured to displaying a first color, the first sub-pixel comprises a first electrode and a first light-emitting layer disposed on the first electrode;
a plurality of second sub-pixels configured to displaying a second color, the second sub-pixel comprises a second electrode and a second light-emitting layer disposed on the second electrode; and
a plurality of third sub-pixels configured to displaying a third color, the third sub-pixel comprises a third electrode and a third light-emitting layer disposed on the third electrode, and the third light-emitting layer is overlapped with at least two adjacently disposed third electrodes;
the display panel further comprises a plurality of light-emitting repeating units, each of the light-emitting repeating units comprises two adjacently disposed light-emitting unit groups, and each of the light-emitting unit groups comprises:
one of the first sub-pixels disposed in a center of a virtual rectangle;
at least one of the second sub-pixels disposed in the virtual rectangle and close to a side edge of the virtual rectangle; and
at least two of the third sub-pixels disposed in the virtual rectangle and adjacent to a common side edge of the virtual rectangle, and the common side edge is a side edge of the virtual rectangle adjacent to a virtual rectangle of another adjacent light-emitting unit group;
wherein third electrodes of the at least two of the third sub-pixels in the light-emitting unit group are electrically connected via a first wire;
in each of the light-emitting repeating units, the two adjacent light-emitting unit groups comprise at least two adjacent third sub-pixels.

2. The display panel of claim 1, wherein each of the light-emitting unit groups comprises at least two of the second sub-pixels, and second electrodes of the at least two of the second sub-pixels of the light-emitting unit group are electrically connected via a second wire.

3. The display panel of claim 2, wherein the second light-emitting layer is overlappingly disposed with at least two adjacently disposed second electrodes, a plurality of second sub-pixels of two adjacent light-emitting repeating units comprise at least one second sub-pixel group, and each second sub-pixel group comprises at least two of the second sub-pixels, and the at least two of the second sub-pixels are respectively disposed in two light-emitting repeating units and disposed adjacent to each other.

4. The display panel of claim 3, wherein two of the second sub-pixels are disposed in one virtual rectangle, and the two of the second sub-pixels are respectively disposed at two top corners of the virtual rectangle distal to the common side edge, in any four of the adjacent light-emitting repeating units, four of the adjacent second sub-pixels share one second light-emitting layer, and the second light-emitting layer is overlappingly disposed with four of the second electrodes.

5. The display panel of claim 1, wherein two of the third sub-pixels are disposed in one virtual rectangle, and two of the third sub-pixels are respectively disposed at two top corners of the virtual sub-rectangle close to the common side edge, and in a direction parallel to the common side edge, four of the adjacent third sub-pixels are disposed in any two adjacent light-emitting repeating units, the four of the third sub-pixels share one third light-emitting layer, and the third light-emitting layer is overlappingly disposed with four of the third electrodes.

6. The display panel of claim 1, wherein in one virtual rectangle, a number of the second sub-pixels is same as a number of the third sub-pixels.

7. The display panel of claim 1, wherein the second light-emitting layer is overlappingly disposed with at least two adjacently disposed second electrodes, at least one of the second sub-pixels in the light-emitting unit group is disposed close to the common side edge, two adjacent light-emitting unit groups comprise two of the second sub-pixels at least partially adjacent to each other, two adjacent second sub-pixels comprise a second common edge, and the second common edge coincides with the common side edge of the virtual rectangle.

8. The display panel of claim 1, wherein the two adjacent light-emitting unit groups are symmetrically disposed with respect to the common side edge.

9. The display panel of claim 1, wherein an area of the first sub-pixel is greater than an area of the second sub-pixel, and the area of the first sub-pixel is greater than an area of the third sub-pixel.

10. The display panel of claim 1, wherein the first sub-pixels, the second sub-pixels, and the third sub-pixels are any combination of red sub-pixels, green sub-pixels, and blue sub-pixels.

11. A mobile terminal, comprising a display panel and a terminal body, the terminal body and the display panel are combined into a whole, and the display panel comprises a plurality of sub-pixels, the plurality of sub-pixel comprises:
a plurality of first sub-pixels configured to displaying a first color, the first sub-pixel comprises a first electrode and a first light-emitting layer disposed on the first electrode;
a plurality of second sub-pixels configured to displaying a second color, the second sub-pixel comprises a second electrode and a second light-emitting layer disposed on the second electrode; and
a plurality of third sub-pixels configured to displaying a third color, the third sub-pixel comprises a third electrode and a third light-emitting layer disposed on the third electrode, and the third light-emitting layer is overlapped with at least two adjacently disposed third electrodes;
the display panel further comprises a plurality of light-emitting repeating units, each of the light-emitting repeating units comprises two adjacently disposed light-emitting unit groups, and each of the light-emitting unit groups comprises:
one of the first sub-pixels disposed in a center of a virtual rectangle;
at least one of the second sub-pixels disposed in the virtual rectangle and close to a side edge of the virtual rectangle; and
at least two of the third sub-pixels disposed in the virtual rectangle and adjacent to a common side edge of the virtual rectangle, and the common side edge is a side edge of the virtual rectangle adjacent to a virtual rectangle of another adjacent light-emitting unit group;
wherein third electrodes of the at least two of the third sub-pixels in the light-emitting unit group are electrically connected via a first wire;
in each of the light-emitting repeating units, the two adjacent light-emitting unit groups comprise at least two adjacent third sub-pixels.

12. The mobile terminal of claim 11, wherein each of the light-emitting unit groups comprises at least two of the second sub-pixels, and second electrodes of the at least two of the second sub-pixels of the light-emitting unit group are electrically connected via a second wire.

13. The mobile terminal of claim 12, wherein the second light-emitting layer is overlappingly disposed with at least two adjacently disposed second electrodes, a plurality of second sub-pixels of two adjacent light-emitting repeating units comprise at least one second sub-pixel group, and each second sub-pixel group comprises at least two of the second sub-pixels, and the at least two of the second sub-pixels are respectively disposed in two light-emitting repeating units and disposed adjacent to each other.

14. The mobile terminal of claim 13, wherein two of the second sub-pixels are disposed in one virtual rectangle, and the two of the second sub-pixels are respectively disposed at two top corners of the virtual rectangle distal to the common side edge, in any four of the adjacent light-emitting repeating units, four of the adjacent second sub-pixels share one second light-emitting layer, and the second light-emitting layer is overlappingly disposed with four of the second electrodes.

15. The mobile terminal of claim 11, wherein two of the third sub-pixels are disposed in one virtual rectangle, and two of the third sub-pixels are respectively disposed at two top corners of the virtual sub-rectangle close to the common side edge, and in a direction parallel to the common side edge, four of the adjacent third sub-pixels are disposed in any two adjacent light-emitting repeating units, the four of the third sub-pixels share one third light-emitting layer, and the third light-emitting layer is overlappingly disposed with four of the third electrodes.

16. The mobile terminal of claim 11, in one virtual rectangle, a number of the second sub-pixels is same as a number of the third sub-pixels.

17. The mobile terminal of claim 11, wherein the second light-emitting layer is overlappingly disposed with at least two adjacently disposed second electrodes, at least one of the second sub-pixels in the light-emitting unit group is disposed close to the common side edge, two adjacent light-emitting unit groups comprise two of the second sub-pixels at least partially adjacent to each other, two adjacent second sub-pixels comprise a second common edge, and the second common edge coincides with the common side edge of the virtual rectangle.

18. The mobile terminal of claim 11, wherein the two adjacent light-emitting unit groups are symmetrically disposed with respect to the common side edge.

19. The mobile terminal of claim 11, wherein an area of the first sub-pixel is greater than an area of the second sub-pixel, and an area of the first sub-pixel is greater than an area of the third sub-pixel.

20. The mobile terminal of claim 11, wherein the first sub-pixels, the second sub-pixels, and the third sub-pixels are any combination of red sub-pixels, green sub-pixels, and blue sub-pixels.
